(19) United States
(12) Patent Application Publication
(10) Pub. No.: US 2025/0201313 A1
(43) Pub. Date: Jun. 19, 2025

(54) MEMORY DEVICE AND OPERATING METHOD THEREOF

(71) Applicant: MACRONIX INTERNATIONAL CO., LTD., HSINCHU (TW)

(72) Inventors: Po-Hao TSENG, Taichung City (TW); Shao-Yu FANG, New Taipei City (TW); Feng-Min LEE, Hsinchu City (TW)

(21) Appl. No.: 18/537,917

(22) Filed: Dec. 13, 2023

(51) Int. Cl. G11C 16/26; G06F 7/50; G11C 16/04; G11C 16/10

(52) U.S. Cl. CPC G11C 16/26; G06F 7/50; G11C 16/0483; G11C 16/10

(57) ABSTRACT

A memory device includes a first memory cell, a first switch element and a second switch element. The first memory cell is configured to store a first data bit, and configured to perform a search operation to the first data bit by a first search bit to generate a first current signal. The first switch element is coupled in series with the first memory cell, and configured to be turned on in response to a clamp voltage level during the search operation, to clamp the first current signal. The second switch element is coupled in series with the first memory cell, and configured to be turned on in response to a first enable voltage level. The first enable voltage level is larger than the clamp voltage level.

### BACKGROUND

### Technical Field

The present disclosure relates to a memory technique. More particularly, the present disclosure relates to a memory device and an operating method of a memory device.

### Description of Related Art

A memory device includes multiple memory cells configured to store data bits. The memory cells can compare the data bits and search bits to perform a search operation. During the search operation, the memory cells generate corresponding current signals according to the comparison results. However, the current signals may be operated in a saturation region having larger variation, such that misunderstanding of matching results of the search operation are produced. Thus, techniques associated with the designing for overcoming the problems described above are important issues in the field.

### SUMMARY

The present disclosure provides a memory device. The memory device includes a first memory cell, a first switch element and a second switch element. The first memory cell is configured to store a first data bit, and configured to perform a search operation to the first data bit by a first search bit to generate a first current signal. The first switch element is coupled in series with the first memory cell, and configured to be turned on in response to a clamp voltage level during the search operation, to clamp the first current signal. The second switch element is coupled in series with the first memory cell, and configured to be turned on in response to a first enable voltage level. The first enable voltage level is larger than the clamp voltage level.

In some embodiment, before the search operation, the first memory cell is further configured to perform a write operation to write the first data bit, and during the write operation, the first switch element turned on in response to the first enable voltage level.

In some embodiment, the memory device further includes a second memory cell and a third switch element. The second memory cell is configured to store a second data bit, and configured to perform the search operation to the second data bit by a second search bit to generate a second current signal. The third switch element is coupled in series with the second memory cell between a first node and a second node, and configured to be turned on in response to the clamp voltage level during the search operation, to clamp the second current signal. The first memory cell and the first switch element are coupled in series between the first node and the second node.

In some embodiment, the memory device further includes a third memory cell and a fourth switch element. The third memory cell is configured to store a third data bit, and configured to perform the search operation to the third data bit by a third search bit to generate a third current signal. The fourth switch element is coupled in series with the third memory cell between the first node and the second node, and configured to be turned on in response to the clamp voltage level during the search operation, to clamp the third current signal.

In some embodiment, the third switch element is coupled to the first switch element at the first node.

In some embodiment, the memory device further includes a fourth switch element. The fourth switch element is coupled in series with the second memory cell, and configured to be turned on in response to the first enable voltage level. The first memory cell is coupled between the first switch element and the second switch element, and the second memory cell is coupled between the third switch element and the fourth switch element.

In some embodiment, the memory device further includes a third switch element and a fourth switch element. The third switch element is configured to be turned on in response to a second enable voltage level during the search operation. The fourth switch element is configured to be turned on in response to the second enable voltage level during the search operation. The first memory cell, the first switch element and the second switch element are coupled in series between the third switch element and the fourth switch element, and the second enable voltage level is different from the first enable voltage level.

In some embodiment, the memory device further includes a third switch element. The third switch element is coupled in series with the first memory cell between the first switch element and the second switch element, and configured to be turned on in response to a second enable voltage level during the search operation. The second enable voltage level is different from the first enable voltage level.

In some embodiment, the memory device further includes a third switch element. The third switch element is configured to be turned on in response to the clamp voltage level during the search operation, to clamp a second current signal. The first memory cell is further configured to perform the search operation to the first data bit and the first search bit to generate the second current signal, the first memory cell comprises a fourth switch element and a fifth switch element coupled in parallel with each other, the fourth switch element is coupled in series with the first switch element, and the fifth switch element is coupled in series with the third switch element.

In some embodiment, the third switch element is coupled to the first switch element at a first node.

In some embodiment, the memory device further includes a sixth switch element. The sixth switch element is coupled in series with the third switch element, and configured to be turned on in response to the first enable voltage level. The fourth switch element is coupled between the first switch element and the second switch element, and the fifth switch element is coupled between the third switch element and the sixth switch element.

In some embodiment, the memory device further includes a sixth switch element and a seventh switch element. The sixth switch element is configured to be turned on in response to a second enable voltage level. The seventh switch element is configured to be turned on in response to the second enable voltage level. The third switch element and the fifth switch element are coupled in series between the sixth switch element and the seventh switch element, and the second enable voltage level is different from the first enable voltage level.

The present disclosure provides an operating method of a memory device. The operating method includes: storing a first data bit by a first memory cell; comparing the first data bit with a first search bit to generate a first current signal; clamping the first current signal by a first switch element according to a clamp voltage level; and turning on a second switch element according to a first enable voltage level. The first current signal flows through the second switch element, and the first enable voltage level is larger than the clamp voltage level.

In some embodiment, the operating method further includes: comparing the first data bit with the first search bit to generate a second current signal; and clamping the second current signal by a third switch element according to the clamp voltage level. The third switch element is couple in parallel with the first switch element.

In some embodiment, the first memory cell comprises a fourth switch element and a fifth switch element, the fourth switch element is coupled in series with the first switch element, and the fifth switch element is coupled in series with the third switch element.

In some embodiment, the operating method further includes: summing the first current signal and the second current signal at a node. The first switch element is coupled to the third switch element at the node.

In some embodiment, the operating method further includes: storing a second data bit by a second memory cell; comparing the second data bit with a second search bit to generate a second current signal; and clamping the second current signal by a third switch element according to the clamp voltage level. The third switch element is coupled in parallel with the first switch element.

In some embodiment, the operating method further includes: summing the first current signal and the second current signal at a node. The first switch element is coupled to the third switch element at the node.

In some embodiment, the operating method further includes: turning on a fourth switch element according to a second enable voltage level different from the first enable voltage level. The first current signal is further flows through the fourth switch element, and the first switch element is coupled between the second switch element and the fourth switch element.

In some embodiment, before comparing the first data bit with the first search bit, the first switch element is turned on according to the first enable voltage level.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a memory system illustrated according to some embodiments of present disclosure.

FIG. 1B is a schematic diagram of a memory device illustrated according to some embodiments of present disclosure.

FIG. 2A is a schematic diagram of a memory device illustrated according to some embodiments of present disclosure.

FIG. 2B is a timing diagram corresponding to operations of the memory device shown in FIG. 2A, illustrated according to some embodiments of present disclosure.

FIG. 3A is a schematic diagram of a memory device illustrated according to some embodiments of present disclosure.

FIG. 3B is a timing diagram corresponding to operations of the memory device shown in FIG. 3A, illustrated according to some embodiments of present disclosure.

FIG. 4A is a schematic diagram of a memory device illustrated according to some embodiments of present disclosure.

FIG. 4B is a timing diagram corresponding to operations of the memory device shown in FIG. 4A, illustrated according to some embodiments of present disclosure.

FIG. 5 is a schematic diagram of a memory device illustrated according to some embodiments of present disclosure.

FIG. 6 is a schematic diagram of a memory device illustrated according to some embodiments of present disclosure.

FIG. 7 is a schematic diagram of a memory device illustrated according to some embodiments of present disclosure.

FIG. 8 is a flow chart diagram of operating method of a memory device illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

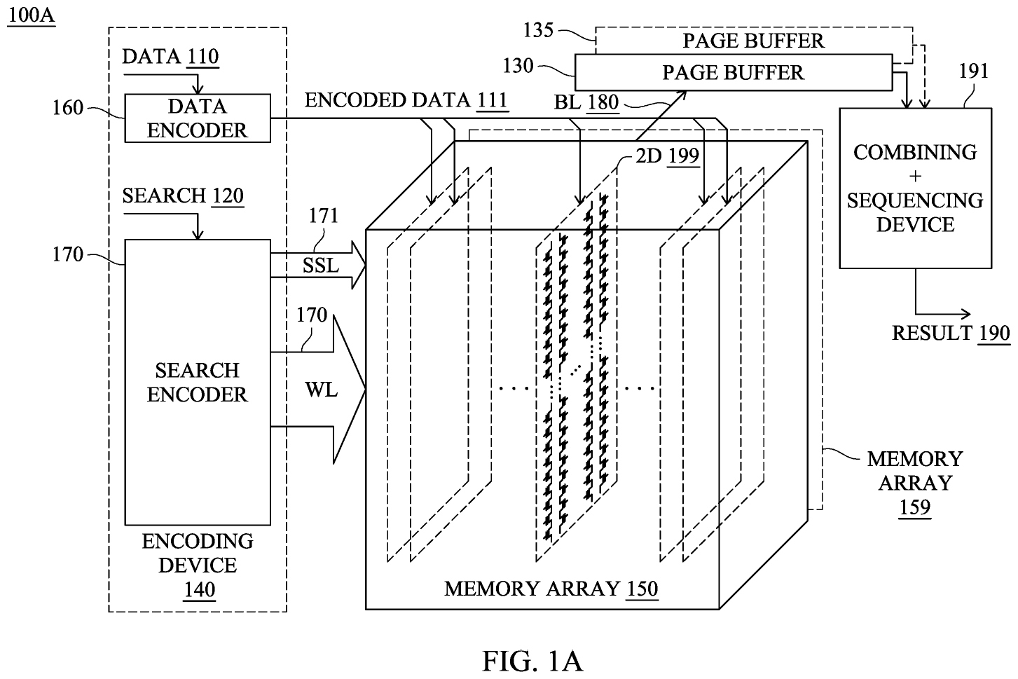

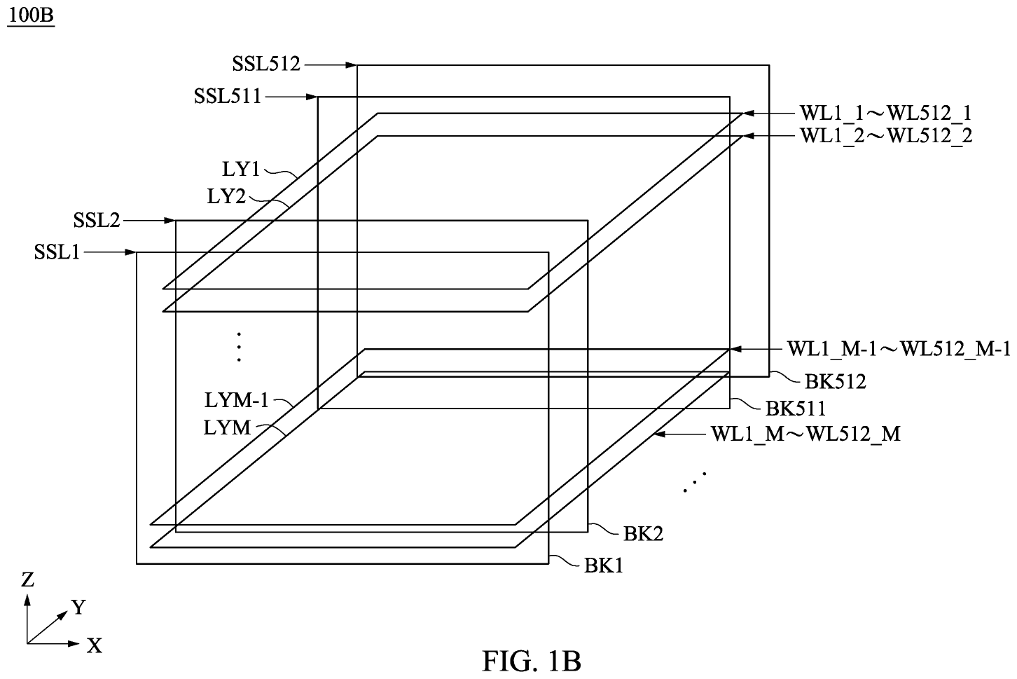

FIG. 1A is a schematic diagram of a memory system 100A illustrated according to some embodiments of present disclosure. In some embodiments, the memory system 100A can be implemented by a 3D NAND in-memory search system. As shown in FIG. 1A, the memory system 100A includes an encoding device 140, memory arrays 150, 159, page buffers 130, 135 and combining/sequencing device 191. The encoding device 140 can includes a data encoder 160 and a search encoder 170. The memory array can include multiple 2D memory arrays 199.

In some embodiments, the data encoder 160 is configured receive data signals 110 and generate encoded data signals 111. The search encoder 170 is configured to receive search signals 120 and generate string select line (SSL) signals 171 and word line (WL) signals 172. The memory array 150 is configured to receive the encoded data signals 111, the string select line signals 171 and word line signals 172, and generate bit line (BL) signals 180. The page buffer 130 is configured to process outputs of the bit line signals 180 to generate search results 190.

In some embodiments, the memory system 100A can be implemented on a single integrated circuit die, multiple integrated circuits, or be implemented as a component of a system-on-a-chip (SOC). As a specific example, the memory system 100A is implemented on a single integrated circuit die, and can perform searching and combining logic operations in the single integrated circuit die.

FIG. 1B is a schematic diagram of a memory device 100B illustrated according to some embodiments of present disclosure. Referring to FIG. 1A and FIG. 1B, the memory device 100B can be an embodiment of the memory array 150.

In some embodiments, the memory device 100B includes multiple memory elements. As shown in FIG. 1B, the memory elements in the memory device 100B can be arranged M layers LY1-LYM and M1 blocks BK1-BK512. It is noted that M is a positive integer. In various embodiments, 512 can be substituted by other positive integers.

In some embodiments, the memory device 100B can be implemented by three-dimensional (3D) memory architecture. For example, the layers LY1-LYM are arranged in order along a Z direction, and each of the layers LY1-LYM extends along X-Y plane. The blocks BK1-BK512 are arranged in order along the Y direction, and each of the blocks BK1-BK512 extends along X-Z plane. However, the present disclosure is not limited to this. In different embodiments, the memory device 100B also can be implemented by two-dimensional (2D) memory architecture. In some embodiments, the X direction, the Y direction and the Z direction are perpendicular with each other.

As shown in FIG. 1B, the layer LY1 is configured to receive word line signal WL1_1-WL512_1. The layer LY2 is configured to receive word line signal WL1_2-WL512_2, and so on. The layer LYM−1 is configured to receive word line signal WL1_M−1-WL512_M−1. The layer LYM is configured to receive word line signal WL1_M-WL512_M.

As shown in FIG. 1B, the blocks BK1-BK512 are configured to receive string select line signals SSL1-SSL512, respectively. In some embodiments, the memory device 100B is configured to store multiple data bits, and perform calculations, such as searching operations and comparison operations to the stored data bit according to the word line signal groups WL1_1-WL512_M and the string select line signals SSL1-SSL512.

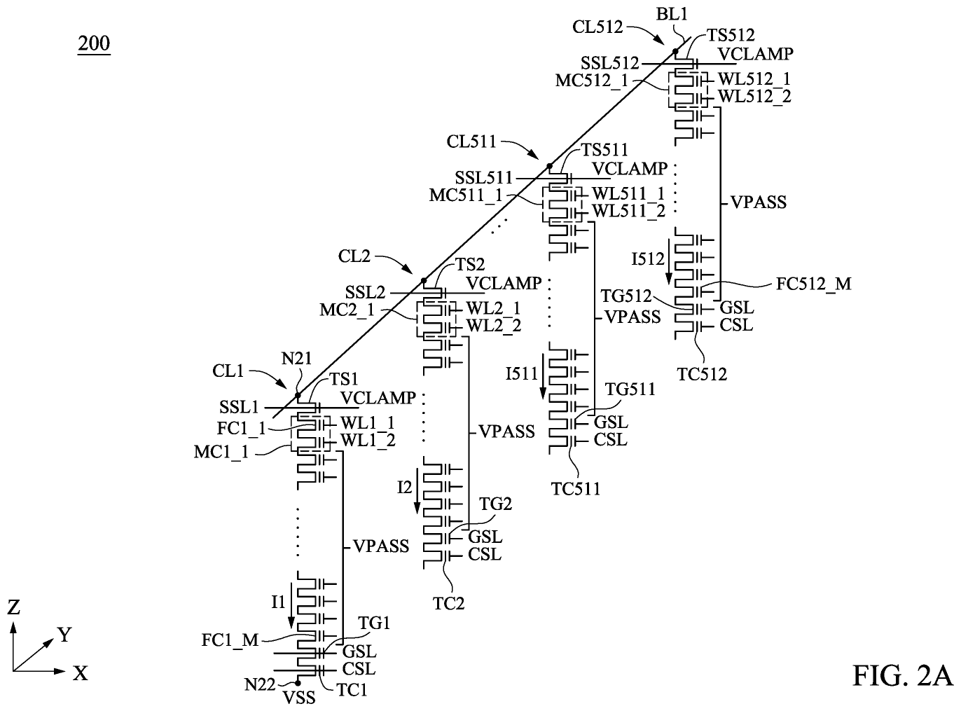

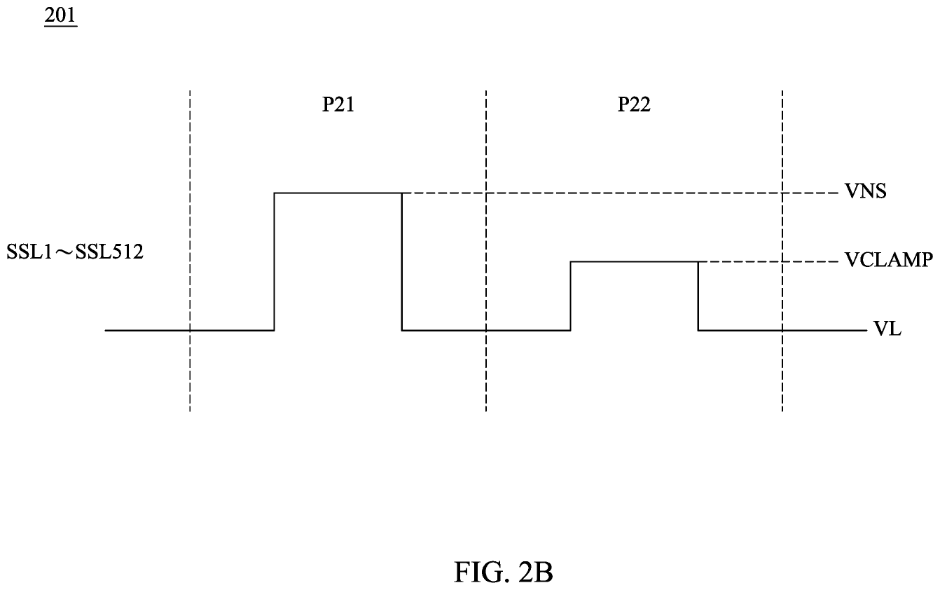

FIG. 2A is a schematic diagram of a memory device 200 illustrated according to some embodiments of present disclosure. As shown in FIG. 2A, the memory device 200 includes 512 memory columns CL1-CL512. The memory columns CL1-CL512 are coupled in parallel with each other between nodes N21 and N22, and are configured to output a bit line signal BL1 at the node N21. In some embodiments, the memory device 200 can includes various numbers of memory columns.

In some embodiments, the memory device 200 can further include other memory columns which are arranged in parallel with the memory columns CL1-CL512 along the X direction and configured to output other bit line signals. For brevity, the other memory columns are not shown in FIG. 2A.

In some embodiments, the memory columns CL1-CL512 are configured to generate current signals I1-I512, respectively, such that the memory device 200 sums the current signals I1-I512 at the node N21 to generate the bit line signal BL1. The current signals I1-I512 flow through the memory columns CL1-CL512, respectively.

As shown in FIG. 2A, the memory column CL1 includes switch elements TS1, FC1_1-FC1_M, TG1 and TC1 coupled in series in order between the nodes N21 and N22. Specifically, a first terminal of the switch element TS1 is coupled to the node N21, and a second terminal of the switch element TS1 is coupled to a first terminal of the switch element FC1_1. A second terminal of the switch element FC1_1 is coupled to a first terminal of the switch element FC1_2, and so on. A second terminal of the switch element FC1_M−1 is coupled to a first terminal of the switch element FC1_M. A second terminal of the switch element FC1_M is coupled to a first terminal of the switch element TG1. A second terminal of the switch element TG1 is coupled to a first terminal of the switch element TC1. A second terminal of the switch element TC1 is coupled to the node N22.

In some embodiments, the switch element TS1 is configured to output the current signal I1 at the node N21. The switch element TC1 is configured to receive the reference voltage signal VSS at the node N22. The control terminal of the switch element TS1 is configured to receive the string select line signal SSL1. The control terminals of the switch elements FC1_1-FC1_M are configured to receive the word line signals WL1_1-WL1_M, respectively. The control terminal of the switch element TG1 is configured to receive a ground select line signal GSL. The control terminal of the switch element TC1 is configured to receive the control select line signal CSL.

As shown in FIG. 2A, the memory column CL2 includes switch elements TS2, FC2_1-FC2_M, TG2 and TC2 coupled in series in order between the nodes N21 and N22. Specifically, a first terminal of the switch element TS2 is coupled to the node N21, and a second terminal of the switch element TS2 is coupled to a first terminal of the switch element FC2_1. A second terminal of the switch element FC2_1 is coupled to a first terminal of the switch element FC2_2, and so on. A second terminal of the switch element FC2_M−1 is coupled to a first terminal of the switch element FC2_M. A second terminal of the switch element FC2_M is coupled to a first terminal of the switch element TG2. A second terminal of the switch element TG2 is coupled to a first terminal of the switch element TC2. A second terminal of the switch element TC2 is coupled to the node N22.

In some embodiments, the switch element TS2 is configured to output the current signal I2 at the node N21. The switch element TC2 is configured to receive the reference voltage signal VSS at the node N22. The control terminal of the switch element TS2 is configured to receive the string select line signal SSL2. The control terminals of the switch elements FC2_1-FC2_M are configured to receive the word line signals WL2_1-WL2_M, respectively. The control terminal of the switch element TG2 is configured to receive the ground select line signal GSL. The control terminal of the switch element TC2 is configured to receive the control select line signal CSL. In some embodiments, the ground select line signal GSL is a collective name of the ground select line signal GSL1-GSL512, and the control select line signal CSL is a collective name of the control select line signal CSL1-CSL512.

As shown in FIG. 2A, the memory column CL511 includes switch elements TS511, FC511_1-FC511_M, TG511 and TC511 coupled in series in order between the nodes N21 and N22. Specifically, a first terminal of the switch element TS511 is coupled to the node N21, and a second terminal of the switch element TS511 is coupled to a first terminal of the switch element FC511_1. A second terminal of the switch element FC511_1 is coupled to a first terminal of the switch element FC511_2, and so on. A second terminal of the switch element FC511_M−1 is coupled to a first terminal of the switch element FC511_M. A second terminal of the switch element FC511_M is coupled to a first terminal of the switch element TG511. A second terminal of the switch element TG511 is coupled to a first terminal of the switch element TC511. A second terminal of the switch element TC511 is coupled to the node N22.

In some embodiments, the switch element TS511 is configured to output the current signal I511 at the node N21. The switch element TC511 is configured to receive the reference voltage signal VSS at the node N22. The control terminal of the switch element TS511 is configured to receive the string select line signal SSL511. The control terminals of the switch elements FC511_1-FC511_M are configured to receive the word line signals WL511_1-WL511_M, respectively. The control terminal of the switch element TG511 is configured to receive the ground select line signal GSL. The control terminal of the switch element TC511 is configured to receive the control select line signal CSL.

As shown in FIG. 2A, the memory column CL512 includes switch elements TS512, FC512_1-FC512_M, TG512 and TC512 coupled in series in order between the nodes N21 and N22. Specifically, a first terminal of the switch element TS512 is coupled to the node N21, and a second terminal of the switch element TS512 is coupled to a first terminal of the switch element FC512_1. A second terminal of the switch element FC512_1 is coupled to a first terminal of the switch element FC512_2, and so on. A second terminal of the switch element FC512_M−1 is coupled to a first terminal of the switch element FC512_M. A second terminal of the switch element FC512_M is coupled to a first terminal of the switch element TG512. A second terminal of the switch element TG512 is coupled to a first terminal of the switch element TC512. A second terminal of the switch element TC512 is coupled to the node N22.

In some embodiments, the switch element TS512 is configured to output the current signal I512 at the node N21. The switch element TC512 is configured to receive the reference voltage signal VSS at the node N22. The control terminal of the switch element TS512 is configured to receive the string select line signal SSL512. The control terminals of the switch elements FC512_1-FC512_M are configured to receive the word line signals WL512_1-WL512_M, respectively. The control terminal of the switch element TG512 is configured to receive the ground select line signal GSL. The control terminal of the switch element TC512 is configured to receive the control select line signal CSL.

In some embodiments, the switch elements TS1-TS512, TG1-TS512 and TS1-TS512 can be implemented by charge trap free elements (such as transistors) or elements having charge trap layer (such as flash cell). The switch elements FC1_1-FC512_M can be implemented by flash cell.

Referring to FIG. 1B and FIG. 2A, the memory device 200 can be an embodiment of the memory device 100B. For example, the memory columns CL1-CL512 can be included in the blocks BK1-BK512, respectively. The switch elements FC1_1-FC512_1 can be included in the layer LY1. The switch elements FC1_2-FC512_2 can be included in the layer LY2, and so on. The switch elements FC1_M−1-FC512_M−1 can be included in the layer LYM−1. The switch elements FC1_M-FC512_M can be included in the layer LYM.

In some embodiments, two switch elements coupled in series in the switch elements FC1_1-FC512_M can be formed as one memory cell for storing a data bit.

For example, the switch elements FC1_1 and FC1_2 are configured to be formed as a memory cell MC1_1 for storing a data bit BT1. The switch elements FC2_1 and FC2_2 are configured to be formed as a memory cell MC2_1 for storing a data bit BT2. The switch elements FC511_1 and FC511_2 are configured to be formed as a memory cell MC511_1 for storing a data bit BT511. The switch elements FC512_1 and FC512_2 are configured to be formed as a memory cell MC1_12_1 for storing a data bit BT512. The other switch elements in the switch elements FC1_1-FC512_M can be formed as other memory cells for storing other data bit. However, for brevity, details of the other memory cells are not described again herein.

In some embodiments, the memory device 200 can perform a write operation and a search operation in order. During the write operation, data signals are applied to memory cells, to change threshold voltage levels of the memory cells. For example, when the data bit BT1 has a logic value 0, the switch elements FC1_1 and FC1_2 have threshold voltage levels VTH and VTL, respectively. When the data bit BT1 has a logic value 1, the switch elements FC1_1 and FC1_2 have the threshold voltage levels VTL and VTH, respectively. In some embodiments, the threshold voltage level VTL is smaller than the threshold voltage level VTH.

Similarly, when the data bit BT2 has the logic value 0, the switch elements FC2_1 and FC2_2 have threshold voltage levels VTH and VTL, respectively. When the data bit BT2 has the logic value 1, the switch elements FC2_1 and FC2_2 have the threshold voltage levels VTL and VTH, respectively, and so on. When the data bit BT511 has the logic value 0, the switch elements FC511_1 and FC511_2 have threshold voltage levels VTH and VTL, respectively. When the data bit BT511 has the logic value 1, the switch elements FC511_1 and FC511_2 have the threshold voltage levels VTL and VTH, respectively. When the data bit BT512 has the logic value 0, the switch elements FC512_1 and FC512_2 have threshold voltage levels VTH and VTL, respectively. When the data bit BT512 has the logic value 1, the switch elements FC512_1 and FC512_2 have the threshold voltage levels VTL and VTH, respectively.

In some embodiments, the word line signals can carry search bits. For example, the word line signals WL1_1 and WL1_2 can carry a search bit SB1 together. The word line signals WL2_1 and WL2_2 can carry a search bit SB2 together. The word line signals WL511_1 and WL511_2 can carry a search bit SB511 together. The word line signals WL512_1 and WL512_2 can carry a search bit SB512 together.

In some embodiments, the logic bits of the search bits correspond to voltage levels of the word line signals. For example, when the search bit SB1 has the logic value 0, the word line signals WL1_1 and WL1_2 has voltage levels VSH and VSL, respectively. When the search bit SB1 has the logic value 1, the word line signals WL1_1 and WL1_2 has the voltage levels VSL and VSH, respectively. In some embodiments, the voltage level VSH is larger than the voltage level VSL.

Similarly, when the search bit SB2 has the logic value 0, the word line signals WL2_1 and WL2_2 has voltage levels VSH and VSL, respectively. When the search bit SB2 has the logic value 1, the word line signals WL2_1 and WL2_2 has the voltage levels VSL and VSH, respectively, and so on. When the search bit SB511 has the logic value 0, the word line signals WL511_1 and WL511_2 has voltage levels VSH and VSL, respectively. When the search bit SB511 has the logic value 1, the word line signals WL511_1 and WL511_2 has the voltage levels VSL and VSH, respectively. When the search bit SB512 has the logic value 0, the word line signals WL512_1 and WL512_2 has voltage levels VSH and VSL, respectively. When the search bit SB512 has the logic value 1, the word line signals WL512_1 and WL512_2 has the voltage levels VSL and VSH, respectively.

During the search operation, the memory cells receive the word line signals, to compare the search bits and the data bits, and determines current levels of the corresponding current signals according to the comparison result. For example, when each of the data bits BT1 and the search bit SB1 has the logic value 0, the switch elements FC1_1 and FC1_2 have threshold voltage levels VTH and VTL, respectively, and the word line signals WL1_1 and WL1_2 has voltage levels VSH and VSL, respectively, such that the current signal I1 has a current level ILH.

Similarly, when each of the data bits BT1 and the search bit SB1 has the logic value 1, the switch elements FC1_1 and FC1_2 have threshold voltage levels VTL and VTH, respectively, and the word line signals WL1_1 and WL1_2 has voltage levels VSL and VSH, respectively, such that the current signal I1 has the current level ILH.

On the other hand, when the data bits BT1 and the search bit SB1 have the logic values 0 and 1, respectively, the switch elements FC1_1 and FC1_2 have threshold voltage levels VTH and VTL, respectively, and the word line signals WL1_1 and WL1_2 has voltage levels VSL and VSH, respectively, such that the current signal I1 has a current level ILL.

Similarly, when the data bits BT1 and the search bit SB1 have the logic values 1 and 0, respectively, the switch elements FC1_1 and FC1_2 have threshold voltage levels VTL and VTH, respectively, and the word line signals WL1_1 and WL1_2 has voltage levels VSH and VSL, respectively, such that the current signal I1 has the current level ILL.

In summary, when the logic values of the data bits BT1 and the search bit SB1 are the same, the current signal I1 has the current level ILH. When the logic values of the data bits BT1 and the search bit SB1 are different, the current signal I1 has the current level ILL.

Similarly, when the logic values of the data bits BT2 and the search bit SB2 are the same, the current signal I2 has the current level ILH. When the logic values of the data bits BT2 and the search bit SB2 are different, the current signal I2 has the current level ILL, and so on. When the logic values of the data bits BT511 and the search bit SB511 are the same, the current signal I511 has the current level ILH. When the logic values of the data bits BT511 and the search bit SB511 are different, the current signal I511 has the current level ILL. When the logic values of the data bits BT512 and the search bit SB512 are the same, the current signal I512 has the current level ILH. When the logic values of the data bits BT512 and the search bit SB512 are different, the current signal I512 has the current level ILL.

In some embodiments, the current level ILH is larger than the current level ILL. In some embodiments, when a switch element having the threshold voltage level VTH receives a word line signal having the voltage level VSL, the switch element is considered as being turned off, and the current level ILL is considered as zero current level.

When the search operation is performed to the memory cells MC1_1-MC1_12_1, the switch elements TS1-TS512, TG1-TG512, TC1-TC512, FC1_3-FC1_M, . . . , FC511_3-FC511_M and FC512_3-FC512_M are turned on. At this moment, the current signals I1, I2, I511 and I512 correspond to comparison results of the memory cells MC1_1-MC1_12_1, such that a current level of the bit line signal BL1 can correspond to a similarity between the data bits BT1-BT512 and the search bits SB1-SB512.

For example, when the data bits BT1-BT512 have logic values 1, 0, 1, 0, respectively, and the search bits SB1-SB512 have logic values 1, 0, 1, 0, respectively, the similarity between the data bits BT1-BT512 and the search bits SB1-SB512 is 100%. Accordingly, each of the current signals I1, I2, I511 and I512 has the current level ILH, such that the current level of the bit line signal BL1 is larger.

For another example, when the data bits BT1-BT512 have logic values 1, 0, 0, 1, respectively, and the search bits SB1-SB512 have logic values 1, 0, 1, 0, respectively, the similarity between the data bits BT1-BT512 and the search bits SB1-SB512 is 50%. Accordingly, each of the current signals I1 and I2 has the current level ILH and each of the current signals I511 and I512 has the current level ILL, such that the current level of the bit line signal BL1 is smaller than the current level in the example described above with 100% similarity.

For further example, when the data bits BT1-BT512 have logic values 0, 1, 0, 1, respectively, and the search bits SB1-SB512 have logic values 1, 0, 1, 0, respectively, the similarity between the data bits BT1-BT512 and the search bits SB1-SB512 is 0%. Accordingly, each of the current signals I1, I2, I511 and I512 has the current level ILL, such that the current level of the bit line signal BL1 is smaller than the current level in the example described above with 50% similarity.

In the embodiments shown in FIG. 2A, during the search operation, each of the ground select line signals GSL1-GSL512 and the control select line signals CSL1-CSL512 has an enable voltage level VNS, such that each of the switch elements TG1-TG512 and TC1-TC512 is turned on. Each of the word line signals WL1_3-WL1_M, . . . , WL511_3-WL511_M and WL512_3-WL512_M has an enable voltage level VPASS, such that each of the switch elements FC1_3-FC1_M, . . . , FC511_3-FC511_M and FC512_3-FC512_M is turned on. In some embodiments, the enable voltage level VNS corresponds to a normal select voltage level, and the enable voltage level VPASS corresponds to a normal pass voltage level.

On the other hand, during the search operation, each of the string select line signals SSL1-SSL512 has a clamp voltage level VCLAMP, such that each of the switch elements TS1-TS512 is turned on simultaneously. In some embodiments, the clamp voltage level VCLAMP is smaller than the enable voltage level VNS, such that the switch elements TS1-TS512 can clamp the current signals I1-I512 at a linear region instead of a saturation region. Alternatively stated, the switch elements TS1-TS512 turned on in response to the clamp voltage level VCLAMP constrain an upper limit of the current levels of the current signals I1-I512.

In some approaches, during the search operation, string select line signals have a higher enable voltage level, such that the switch elements receiving the string select line signals operate in a saturation region. As a result, variation of current signals outputted from the switch elements is larger, such that misunderstandings for matching results of the search operation are produced.

Compared to above approaches, in some embodiments of present disclosure, the switch elements TS1-TS512 are turned on in response to the lower clamp voltage level VCLAMP, such that the current signals I1-I512 are clamped at the linear region with smaller variation. As a result, misunderstandings of matching results are reduced.

In some embodiments, the switch elements TS1-TS512 can be implemented by charge trap free elements. In the embodiments described above, the enable voltage level VNS is in a voltage range of 1-3 volt, and the clamp voltage level VPASS is in a voltage range of 0-1 volt. For example, the enable voltage level VNS and the clamp voltage level VPASS can be 2 volt and 0.5 volt, respectively.

In some embodiments, the switch elements TS1-TS512 can be implemented by elements having charge trap layer, and have threshold voltage level in a voltage range of 3-4 volt. In the embodiments described above, the enable voltage level VNS is in a voltage range of 5-8 volt, and the clamp voltage level VCLAMP is in a voltage range of 3-5 volt. For example, the enable voltage level VNS and the clamp voltage level VCLAMP can be 7 volt and 4 volt, respectively.

In some embodiments, the search operation can be performed to different memory cell layers in order. For example, after the search operation is performed to a first memory cell layer including the switch elements FC1_1-FC512_1 and FC1_2-FC512_2, the search operation can be performed to a second memory cell layer including the switch elements FC1_3-FC512_3 and FC1_4-FC512_4, and so on. After the search operation is performed to the second memory cell layer, the search operation can be performed to following memory cell layers in order.

Specifically, when the search operation is performed to the second memory cell layer, the word line signals WL1_3-WL512_3 and WL1_4-WL512_4 carry corresponding search bits and have corresponding voltage levels. At this time, the word line signals WL1_1-WL512_1 and WL1_2-WL512_2 have the enable voltage level VPASS, such that the switch elements FC1_1-FC512_1 and FC1_2-FC512_2 are turned on. During the following search operations, the word line signals performing the search operations carry corresponding search bits and have corresponding voltage levels, and the other word line signals have the enable voltage level VPASS, such that the corresponding switch elements are turned on.

FIG. 2B is a timing diagram 201 corresponding to operations of the memory device 200 shown in FIG. 2A, illustrated according to some embodiments of present disclosure. As shown in FIG. 2B, the timing diagram 201 includes periods P21 and P22 arranged in order.

In some embodiments, the memory device 200 can perform a write operation, such as a program operation or an erase operation, during the period P21. Correspondingly, during the period P21, the string select line signals SSL1-SSL512 have the enable voltage level VNS, to write the data bits into the memory cells.

In some embodiments, the memory device 200 can perform a read operation, such as the search operation described above, during the period P22. Correspondingly, during the period P22, the string select line signals SSL1-SSL512 have the clamp voltage level VCLAMP, such that the current signals I1-I512 are clamped at the linear region.

In some embodiments, when the memory device 200 does not perform the write operation and does not perform the read operation, the string select line signals SSL1-SSL512 have a disable voltage level VL, such that the switch elements TS1-TS512 are turned off. In some embodiments, the disable voltage level VL is smaller than the clamp voltage level VCLAMP. In some embodiments, the disable voltage level VL is the ground voltage level.

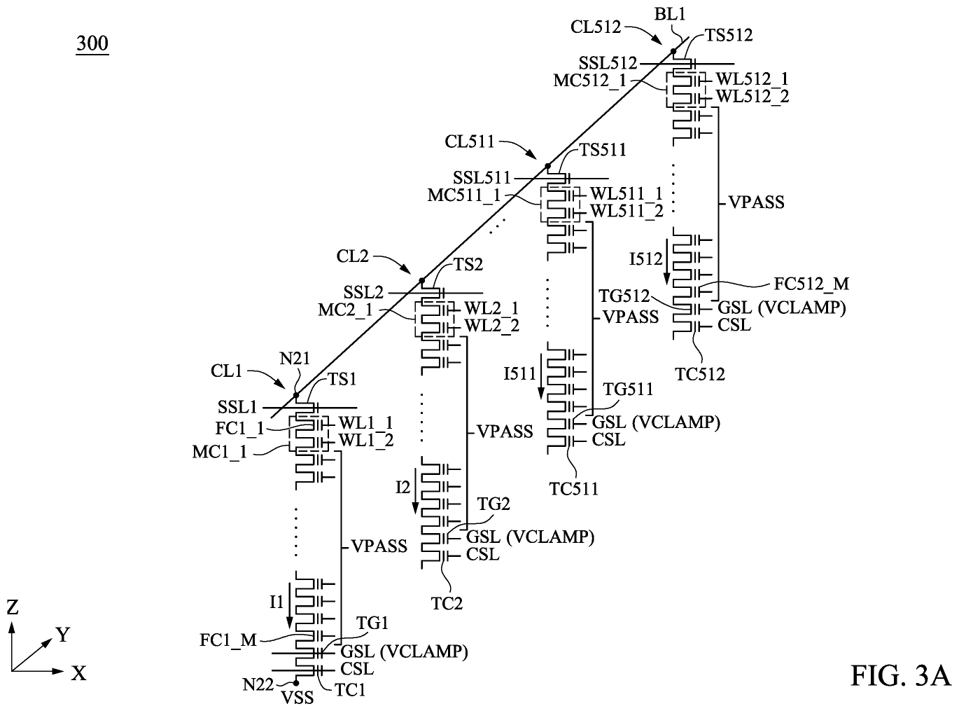

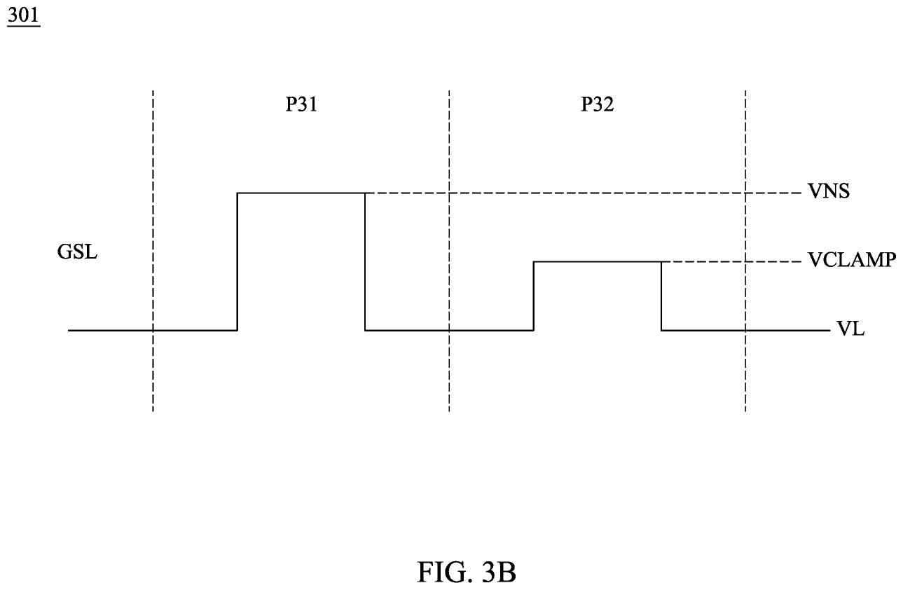

FIG. 3A is a schematic diagram of a memory device 300 illustrated according to some embodiments of present disclosure. Referring to FIG. 3A and FIG. 2A, the memory device 300 is an alternative embodiment of the memory device 200. FIG. 3A follows a similar labeling convention to that of FIG. 2A. For brevity, the discussion will focus more on differences between FIG. 3A and FIG. 2A than on similarities.

Comparing with the memory device 200, when the memory device 300 performs the search operation, each of the ground select line signals GSL1-GSL512 has the clamp voltage level VCLAMP, and each of the string select line signals SSL1-SSL512 has the enable voltage level VNS.

In the embodiment shown in FIG. 3A, each of the switch elements TS1-TS512 is turned on in response to the enable voltage level VNS, and the switch elements TG1-TG512 are turned on simultaneously in response to the clamp voltage level VCLAMP. At this moment, the switch elements TG1-TG512 constrain the upper limit of the current levels of the current signals I1-I512, such that the current signals I1-I512 are clamped at the linear region instead of the saturation region.

In some approaches, during the search operation, ground select line signals have a higher enable voltage level, such that the switch elements receiving the ground select line signals operate in the saturation region. As a result, variation of current signals outputted from the switch elements is larger, such that misunderstandings for matching results of the search operation are produced.

Compared to above approaches, in some embodiments of present disclosure, the switch elements TG1-TG512 are turned on in response to the lower clamp voltage level VCLAMP, such that the current signals I1-I512 are clamped at the linear region with smaller variation. As a result, misunderstandings of matching results are reduced.

In some embodiments, the switch elements TG1-TG512 can be implemented by charge trap free elements. In the embodiments described above, the enable voltage level VNS is in a voltage range of 1-3 volt, and the clamp voltage level VCLAMP is in a voltage range of 0-1 volt. For example, the enable voltage level VNS and the clamp voltage level VCLAMP can be 2 volt and 0.5 volt, respectively.

In some embodiments, the switch elements TG1-TG512 can be implemented by elements having charge trap layer, and have threshold voltage level in a voltage range of 3-4 volt. In the embodiments described above, the enable voltage level VNS is in a voltage range of 5-8 volt, and the clamp voltage level VCLAMP is in a voltage range of 3-5 volt. For example, the enable voltage level VNS and the clamp voltage level VCLAMP can be 7 volt and 4 volt, respectively.

FIG. 3B is a timing diagram 301 corresponding to operations of the memory device 300 shown in FIG. 3A, illustrated according to some embodiments of present disclosure. As shown in FIG. 3B, the timing diagram 301 includes periods P31 and P32 arranged in order.

In some embodiments, the memory device 300 can perform a write operation, such as a program operation or an erase operation, during the period P31. Correspondingly, during the period P31, the ground select line signals GSL1-GSL512 have the enable voltage level VNS, to write the data bits into the memory cells.

In some embodiments, the memory device 300 can perform a read operation, such as the search operation described above, during the period P32. Correspondingly, during the period P32, the ground select line signals GSL1-GSL512 have the clamp voltage level VCLAMP, such that the memory device 300 clamps the current signals I1-I512 at the linear region.

In some embodiments, when the memory device 300 does not perform the write operation and does not perform the read operation, the ground select line signals GSL1-GSL512 have the disable voltage level VL, such that the switch elements TS1-TS512 are turned off.

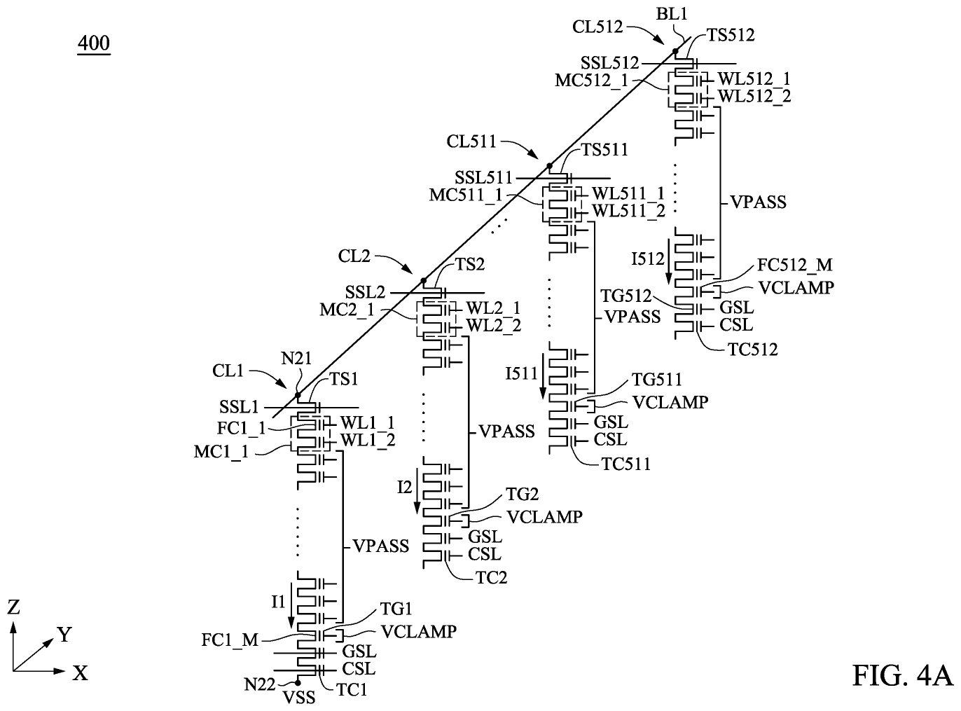

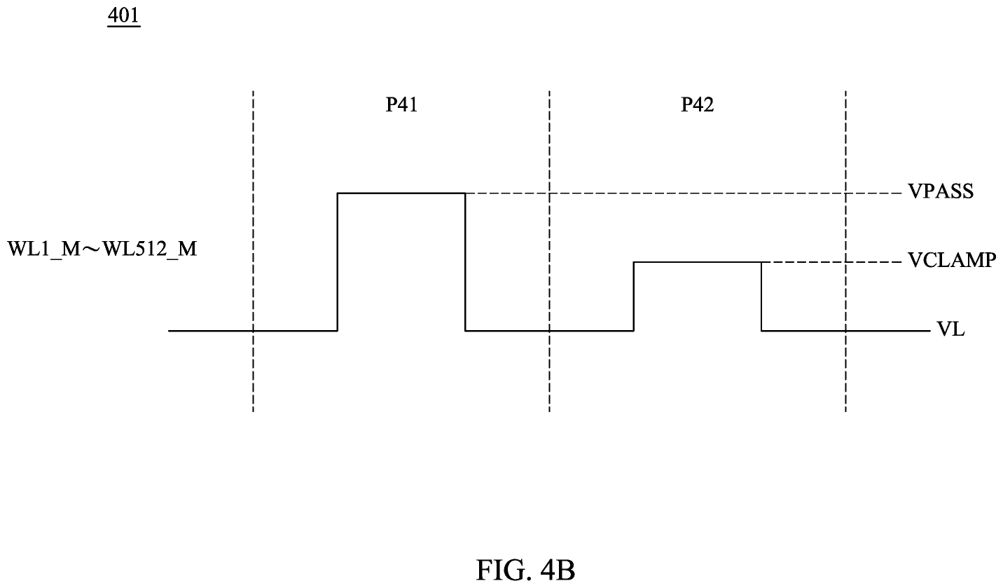

FIG. 4A is a schematic diagram of a memory device 400 illustrated according to some embodiments of present disclosure. Referring to FIG. 4A and FIG. 2A, the memory device 400 is an alternative embodiment of the memory device 200. FIG. 4A follows a similar labeling convention to that of FIG. 2A. For brevity, the discussion will focus more on differences between FIG. 4A and FIG. 2A than on similarities.

Comparing with the memory device 200, when the memory device 400 performs the search operation, each of the word line signals WL1_M-WL512_M has the clamp voltage level VCLAMP, and each of the string select line signals SSL1-SSL512 has the enable voltage level VNS.

In the embodiment shown in FIG. 4A, each of the switch elements TS1-TS512 is turned on in response to the enable voltage level VNS, and the switch elements FC1_M-FC512_M are turned on simultaneously in response to the clamp voltage level VCLAMP. At this moment, the switch elements FC1_M-FC512_M constrain the upper limit of the current levels of the current signals I1-I512, such that the memory device 400 clamps the current signals I1-I512 at the linear region instead of the saturation region.

In some approaches, during the search operation, word line signals have higher a enable voltage level, such that the switch elements receiving the word line signals operate in the saturation region. As a result, variation of current signals outputted from the switch elements is larger, such that misunderstandings for matching results of the search operation are produced.

Compared to above approaches, in some embodiments of present disclosure, the switch elements FC1_M-FC512_M are turned on in response to the lower clamp voltage level VCLAMP, such that the current signals I1-I512 are clamped at the linear region with smaller variation. As a result, misunderstandings of matching results are reduced.

In some embodiments, the switch elements FC1_M-FC512_M can be implemented by flash cells, and have threshold voltage level in a voltage range of 5-6 volt. In the embodiments described above, the enable voltage level VPASS is in a voltage range of 7-8 volt, and the clamp voltage level VCLAMP is in a voltage range of 5-7 volt. For example, the enable voltage level VPASS and the clamp voltage level VCLAMP can be 7 volt and 6 volt, respectively.

In various embodiments, the memory device 400 can also clamp the current signals I1-I512 by switch elements other than the switch elements FC1_M-FC512_M. For example, in some alternative embodiments, the memory device 400 can also clamp the current signals I1-I512 by the switch elements FC1_M−1-FC512_M−1.

In the example described above, each of the word line signals WL1_M-WL512_M has the enable voltage level VPASS, such that the switch elements FC1_M-FC512_M are turned on. Each of the word line signals WL1_M−1-WL512_M−1 has the clamp voltage level VCLAMP, such that the switch elements FC1_M−1-FC512_M−1 clamp the current signals I1-I512 at the linear region.

FIG. 4B is a timing diagram 401 corresponding to operations of the memory device 400 shown in FIG. 4A, illustrated according to some embodiments of present disclosure. As shown in FIG. 4B, the timing diagram 401 includes periods P41 and P42 arranged in order.

In some embodiments, the memory device 400 can perform a write operation, such as a program operation or an erase operation, during the period P41. Correspondingly, during the period P41, word line signals WL1_M-WL512_M have the enable voltage level VPASS, to write the data bits into the memory cells.

In some embodiments, the memory device 400 can perform a read operation, such as the search operation described above, during the period P42. Correspondingly, during the period P42, the word line signals WL1_M-WL512_M have the clamp voltage level VCLAMP, such that the current signals I1-I512 are clamped at the linear region.

In some embodiments, when the memory device 400 does not perform the write operation and does not perform the read operation, the word line signals WL1_M-WL512_M have the disable voltage level VL, such that the switch elements FC1_M-FC512_M are turned off.

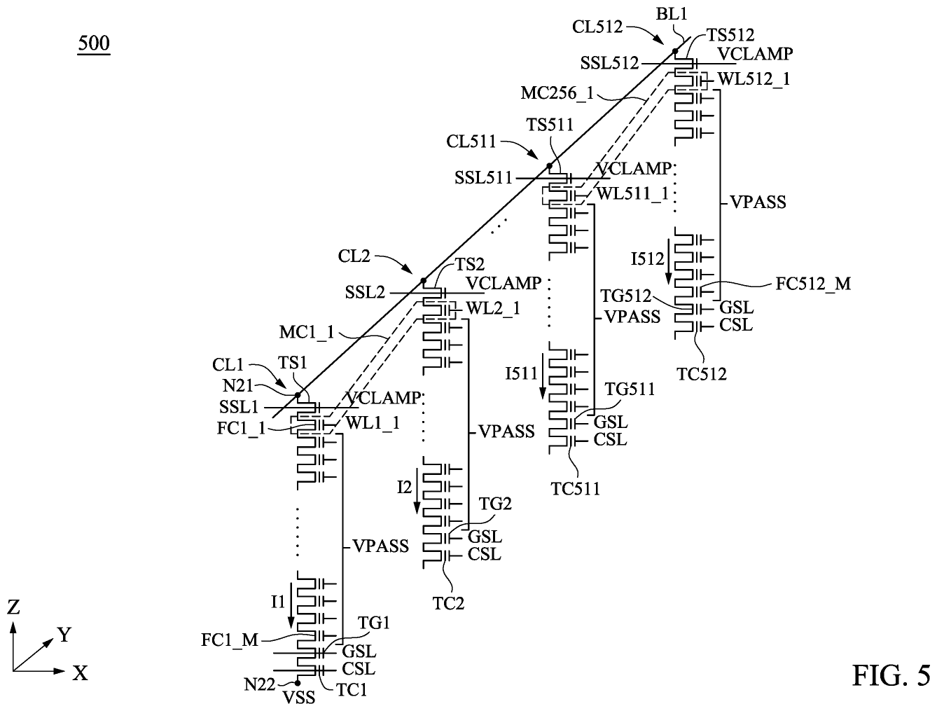

FIG. 5 is a schematic diagram of a memory device 500 illustrated according to some embodiments of present disclosure. Referring to FIG. 5 and FIG. 2A, the memory device 500 is an alternative embodiment of the memory device 200. FIG. 5 follows a similar labeling convention to that of FIG. 2A. For brevity, the discussion will focus more on differences between FIG. 5 and FIG. 2A than on similarities.

Comparing with the memory device 200, in the memory device 500, one memory cell is formed by two switch elements coupled in parallel. For example, the memory cell MC1_1 can be formed by the switch elements FC1_1 and FC2_1 coupled in parallel between the nodes N21 and N22. The memory cell MC256_1 can be formed by the switch elements FC511_1 and FC512_1 coupled in parallel between the nodes N21 and N22. In some embodiments, the memory cells MC1_1 and MC256_1 are configured to store data bits BT1 and BT256, respectively.

In some embodiments, the memory device 500 can perform a write operation and a search operation in order. During the write operation, data signals are applied to memory cells, to change threshold voltage levels of the memory cells. For example, when the data bit BT1 has the logic value 0, the switch elements FC1_1 and FC2_1 have threshold voltage levels VTH and VTL, respectively. When the data bit BT1 has the logic value 1, the switch elements FC1_1 and FC2_1 have the threshold voltage levels VTL and VTH, respectively.

Similarly, when the data bit BT256 has the logic value 0, the switch elements FC511_1 and FC512_1 have threshold voltage levels VTH and VTL, respectively. When the data bit BT256 has the logic value 1, the switch elements FC511_1 and FC512_1 have threshold voltage levels VTL and VTH, respectively.

In the embodiment shown in FIG. 5, the word line signals WL1_1 and WL2_1 carry a search bit SB1 together, and the word line signals WL511_1 and WL512_1 carry a search bit SB52 together.

In some embodiments, when the search bit SB1 has the logic value 0, the word line signals WL1_1 and WL2_1 have the voltage levels VSH and VSL, respectively. When the search bit SB1 has the logic value 1, the word line signals WL1_1 and WL1_2 has the voltage levels VSL and VSH, respectively.

Similarly, when the search bit SB256 has the logic value 0, the word line signals WL511_1 and WL512_1 has voltage levels VSH and VSL, respectively. When the search bit SB256 has the logic value 1, the word line signals WL511_1 and WL512_1 has the voltage levels VSL and VSH, respectively.

During the search operation, the memory cells receive the word line signals, to compare the search bits and the data bits, and determines current levels of the corresponding current signals according to the comparison result. For example, when each of the data bits BT1 and the search bit SB1 has the logic value 0, each of the current signals I1 and I2 has the current level ILL. Similarly, when each of the data bits BT1 and the search bit SB1 has the logic value 1, each of the current signals I1 and I2 has the current level ILL.

On the other hand, when the data bits BT1 and the search bit SB1 have the logic value 0 and 1, respectively, the current signals I1 and I2 have the current level ILH and ILL, respectively. Similarly, when the data bits BT1 and the search bit SB1 have the logic value 1 and 0, respectively, the current signals I1 and I2 have the current level ILL and ILH, respectively.

In summary, when the logic values of the data bits BT1 and the search bit SB1 are the same, each of the current signals I1 and I2 has the current level ILL. When the logic values of the data bits BT1 and the search bit SB1 are different, one of the current signals I1 and I2 has the current level ILH.

Similarly, when the logic values of the data bits BT256 and the search bit SB256 are the same, each of the current signals I511 and I512 has the current level ILL. When the logic values of the data bits BT256 and the search bit SB256 are different, one of the current signals I511 and I512 has the current level ILH.

When the search operation is performed to the memory cells MC1_1-MC256_1, the current signals I1 and I2 correspond to the comparison result of the memory cell MC1_1, and the current signals I511 and I512 correspond to the comparison result of the memory cell MC256_1, such that the current level of the bit line signal BL1 can correspond to a similarity between the data bits BT1-BT256 and the search bits SB1-SB256.

For example, when the data bits BT1, BT256 have logic values 1, 0, respectively, and the search bits SB1, SB256 have logic values 1, 0, respectively, the similarity between the data bits BT1, BT256 and the search bits SB1, SB256 is 100%. Accordingly, each of the current signals I1, I2, I511 and I512 has the current level ILL, such that the current level of the bit line signal BL1 is smaller.

For another example, when the data bits BT1, BT256 have logic values 1, 0, respectively, and the search bits SB1, SB256 have logic values 0, 0, respectively, the similarity between the data bits BT1, BT256 and the search bits SB1, SB256 is 50%. Accordingly, the current signal I2 has the current level ILH, and each of the current signals I1, I511 and I512 has the current level ILL, such that the current level of the bit line signal BL1 is larger than the current level in the example described above with 100% similarity.

For a further example, when the data bits BT1, BT256 have logic values 1, 0, respectively, and the search bits SB1, SB256 have logic values 0, 1, respectively, the similarity between the data bits BT1, BT256 and the search bits SB1, SB256 is 0%. Accordingly, each of the current signals I2 and I511 has the current level ILH, and each of the current signals I1 and I512 has the current level ILL, such that the current level of the bit line signal BL1 is larger than the current level in the example described above with 50% similarity.

In the embodiment shown in FIG. 5, during the search operation, each of the ground select line signal GSL and the control select line signal CSL has the enable voltage level VNS, such that each of the switch elements TG1-TG512 and TC1-TC512 is turned on. Each of the word line signals WL1_2-WL1_M, . . . , WL511_2-WL511_M and WL512_2-WL512_M has the enable voltage level VPASS, such that each of the switch elements FC1_2-FC1_M, . . . , FC511_2-FC511_M and FC512_2-FC512_M is turned on.

On the other hand, during the search operation, each of the string select line signals SSL1-SSL512 has a clamp voltage level VCLAMP, such that the switch elements TS1-TS512 is turned on simultaneously, to clamp the current signals I1-I512 at the linear region instead of the saturation region.

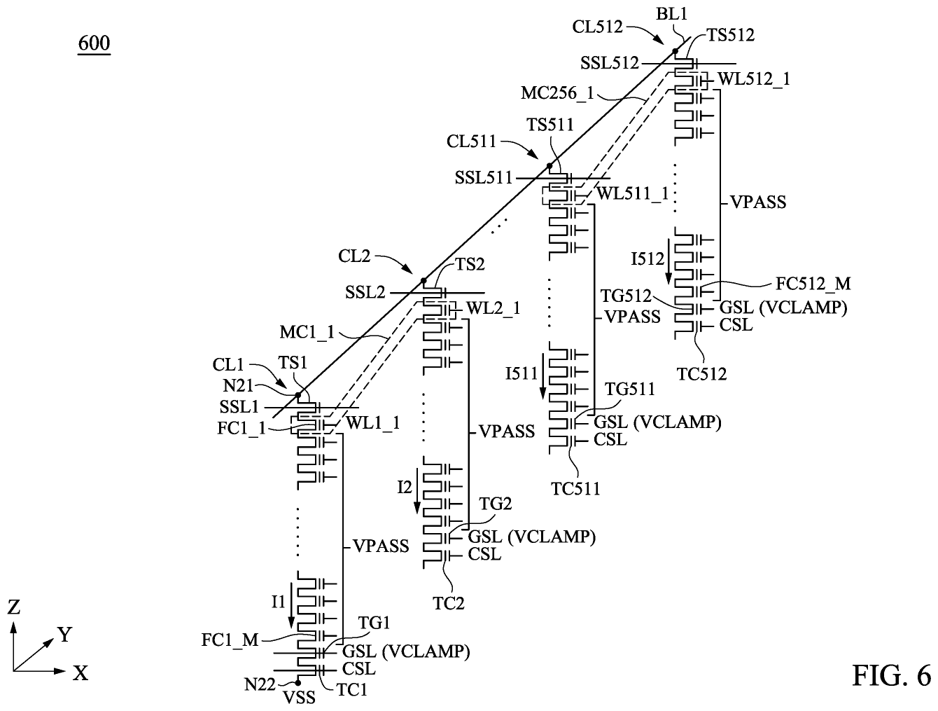

FIG. 6 is a schematic diagram of a memory device 600 illustrated according to some embodiments of present disclosure. Referring to FIG. 6 and FIG. 5, the memory device 600 is an alternative embodiment of the memory device 500. FIG. 6 follows a similar labeling convention to that of FIG. 5. For brevity, the discussion will focus more on differences between FIG. 6 and FIG. 5 than on similarities.

Comparing with the memory device 500, when the memory device 600 performs the search operation, each of the ground select line signal GSL has the clamp voltage level VCLAMP, and each of the string select line signals SSL1-SSL512 has the enable voltage level VNS.

In the embodiment shown in FIG. 6, each of the switch elements TS1-TS512 is turned on in response to the enable voltage level VNS, and the switch elements TG1-TG512 are turned on simultaneously in response to the clamp voltage level VCLAMP. At this moment, the switch elements TG1-TG512 constrain the upper limit of the current levels of the current signals I1-I512, such that the current signals I1-I512 are clamped at the linear region instead of the saturation region.

Referring to FIG. 6 and FIG. 3B, the memory device 600 can operate according to the timing diagram 301. Operations performed by the memory device 600 according to the timing diagram 301 are similar with the operations performed by the memory device 300 according to the timing diagram 301. Therefore, for brevity, some descriptions are not repeated.

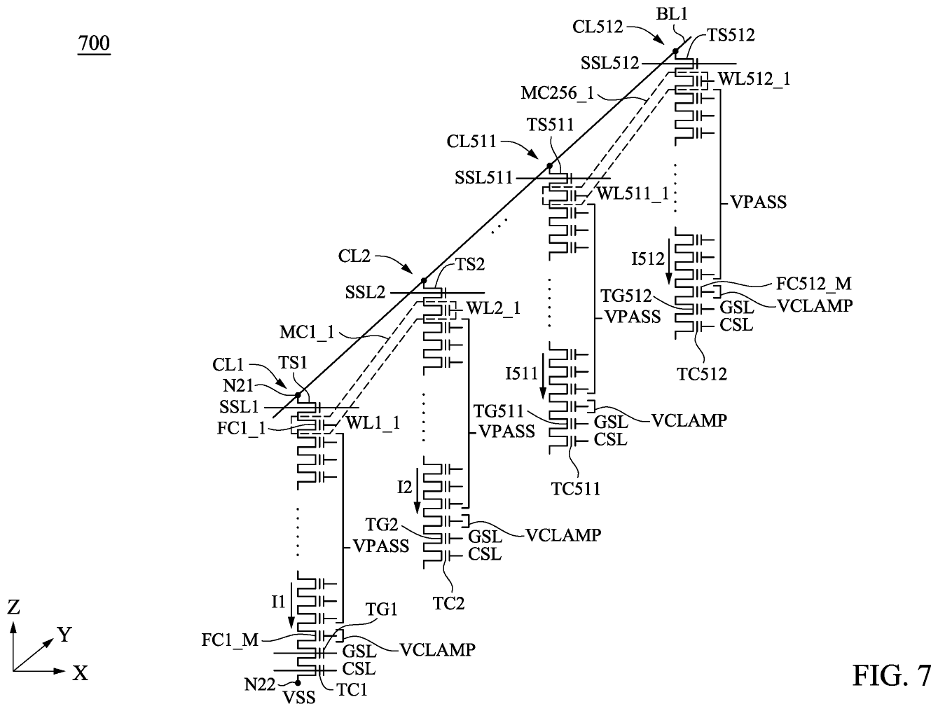

FIG. 7 is a schematic diagram of a memory device 700 illustrated according to some embodiments of present disclosure. Referring to FIG. 7 and FIG. 5, the memory device 700 is an alternative embodiment of the memory device 500. FIG. 7 follows a similar labeling convention to that of FIG. 5. For brevity, the discussion will focus more on differences between FIG. 7 and FIG. 5 than on similarities.

Comparing with the memory device 500, when the memory device 700 performs the search operation, each of the word line signals WL1_M-WL512_M has the clamp voltage level VCLAMP, and each of the string select line signals SSL1-SSL512 has the enable voltage level VNS.

In the embodiment shown in FIG. 7, each of the switch elements TS1-TS512 is turned on in response to the enable voltage level VNS, and the switch elements FC1_M-FC512_M are turned on simultaneously in response to the clamp voltage level VCLAMP. At this moment, the switch elements FC1_M-FC512_M constrain the upper limit of the current levels of the current signals I1-I512, such that the memory device 700 clamps the current signals I1-I512 at the linear region instead of the saturation region.

Referring to FIG. 7 and FIG. 4B, the memory device 700 can operate according to the timing diagram 401. Operations performed by the memory device 600 according to the timing diagram 401 are similar with the operations performed by the memory device 400 according to the timing diagram 401. Therefore, for brevity, some descriptions are not repeated.

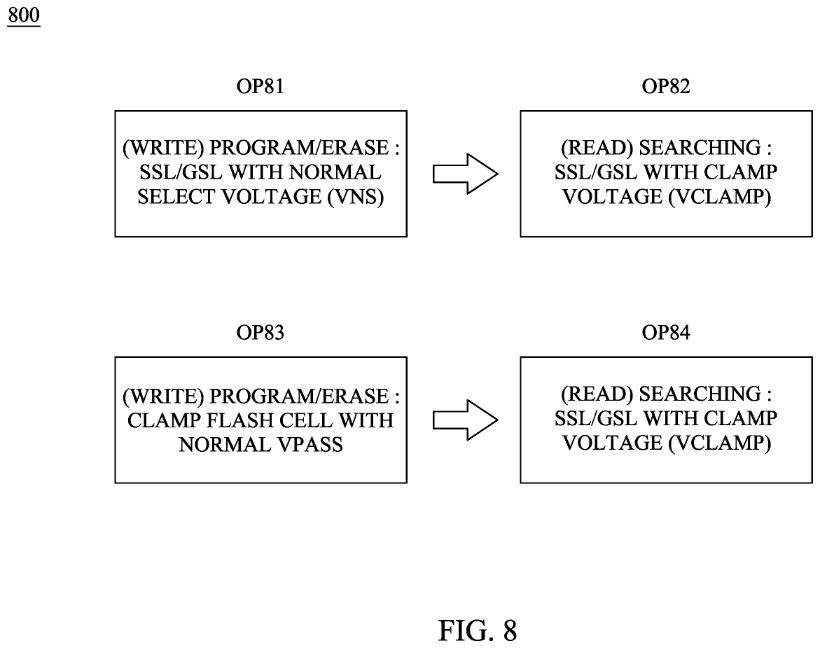

FIG. 8 is a flowchart diagram of an operating method 800 of a memory device illustrated according to some embodiments of present disclosure. As shown in FIG. 8, the operating method 800 can include operations OP81-OP84. In some alternative embodiments, the operating method 800 can also include a part of the operations OP81-OP84.

During the operation OP81, the memory device performs a write operation, such as a program operation or an erase operation. At this moment, the string select line signals SSL1-SSL512 or the ground select line signal GSL has a normal select voltage, such as the enable voltage level VNS.

During the operation OP82, the memory device performs a read operation, such as the search operation. At this moment, the string select line signals SSL1-SSL512 or the ground select line signal GSL has a clamp voltage, such as the clamp voltage level VCLAMP.

Referring to FIG. 2A, FIG. 3A, FIG. 5, FIG. 6 and FIG. 8, the operations OP81-OP82 can be performed by the memory devices 200, 300, 500 and 600. Referring to FIG. 2B and FIG. 3B, the operation OP81 can correspond to the periods P21 and P31, and the operation OP82 can correspond to the periods P22 and P32.

During the operation OP83, the memory device performs a write operation, such as a program operation or an erase operation. At this moment, clamp flash cells, such as the switch elements FC1_M-FC512_M shown in FIG. 4A and FIG. 7, have a normal pass voltage, such as the enable voltage level VPASS.

During the operation OP84, the memory device performs a read operation, such as the search operation. At this moment, the clamp flash cells, such as the switch elements FC1_M-FC512_M shown in FIG. 4A and FIG. 7, have a clamp voltage, such as the clamp voltage level VCLAMP.

Referring to FIG. 4A, FIG. 7 and FIG. 8, the operations OP83-OP84 can be performed by the memory devices 400 and 700. Referring to FIG. 4B, the operation OP83 can correspond to the period P41, and the operation OP84 can correspond to the period P42.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising:
a first memory cell configured to store a first data bit, and configured to perform a search operation to the first data bit by a first search bit to generate a first current signal;
a first switch element coupled in series with the first memory cell, and configured to be turned on in response to a clamp voltage level during the search operation, to clamp the first current signal; and
a second switch element coupled in series with the first memory cell, and configured to be turned on in response to a first enable voltage level,
wherein the first enable voltage level is larger than the clamp voltage level.

2. The memory device of claim 1, wherein before the search operation, the first memory cell is further configured to perform a write operation to write the first data bit, and
during the write operation, the first switch element turned on in response to the first enable voltage level.

3. The memory device of claim 1, further comprising:
a second memory cell configured to store a second data bit, and configured to perform the search operation to the second data bit by a second search bit to generate a second current signal; and
a third switch element coupled in series with the second memory cell between a first node and a second node, and configured to be turned on in response to the clamp voltage level during the search operation, to clamp the second current signal,
wherein the first memory cell and the first switch element are coupled in series between the first node and the second node.

4. The memory device of claim 3, further comprising:
a third memory cell configured to store a third data bit, and configured to perform the search operation to the third data bit by a third search bit to generate a third current signal; and
a fourth switch element coupled in series with the third memory cell between the first node and the second node, and configured to be turned on in response to the clamp voltage level during the search operation, to clamp the third current signal.

5. The memory device of claim 3, wherein the third switch element is coupled to the first switch element at the first node.

6. The memory device of claim 3, further comprising:
a fourth switch element coupled in series with the second memory cell, and configured to be turned on in response to the first enable voltage level,
wherein the first memory cell is coupled between the first switch element and the second switch element, and
the second memory cell is coupled between the third switch element and the fourth switch element.

7. The memory device of claim 1, further comprising:
a third switch element configured to be turned on in response to a second enable voltage level during the search operation; and
a fourth switch element configured to be turned on in response to the second enable voltage level during the search operation,
wherein the first memory cell, the first switch element and the second switch element are coupled in series between the third switch element and the fourth switch element, and
the second enable voltage level is different from the first enable voltage level.

8. The memory device of claim 1, further comprising:
a third switch element coupled in series with the first memory cell between the first switch element and the second switch element, and configured to be turned on in response to a second enable voltage level during the search operation,
wherein the second enable voltage level is different from the first enable voltage level.

9. The memory device of claim 1, further comprising:
a third switch element configured to be turned on in response to the clamp voltage level during the search operation, to clamp a second current signal,
wherein the first memory cell is further configured to perform the search operation to the first data bit and the first search bit to generate the second current signal,
the first memory cell comprises a fourth switch element and a fifth switch element coupled in parallel with each other,
the fourth switch element is coupled in series with the first switch element, and
the fifth switch element is coupled in series with the third switch element.

10. The memory device of claim 9, wherein the third switch element is coupled to the first switch element at a first node.

11. The memory device of claim 9, further comprising:
a sixth switch element coupled in series with the third switch element, and configured to be turned on in response to the first enable voltage level,
wherein the fourth switch element is coupled between the first switch element and the second switch element, and
the fifth switch element is coupled between the third switch element and the sixth switch element.

12. The memory device of claim 9, further comprising:
a sixth switch element configured to be turned on in response to a second enable voltage level; and
a seventh switch element configured to be turned on in response to the second enable voltage level,
wherein the third switch element and the fifth switch element are coupled in series between the sixth switch element and the seventh switch element, and
the second enable voltage level is different from the first enable voltage level.

13. An operating method of a memory device, comprising:
storing a first data bit by a first memory cell;
comparing the first data bit with a first search bit to generate a first current signal;
clamping the first current signal by a first switch element according to a clamp voltage level; and
turning on a second switch element according to a first enable voltage level,
wherein the first current signal flows through the second switch element, and
the first enable voltage level is larger than the clamp voltage level.

14. The operating method of claim 13, further comprising:
comparing the first data bit with the first search bit to generate a second current signal; and
clamping the second current signal by a third switch element according to the clamp voltage level,
wherein the third switch element is couple in parallel with the first switch element.

15. The operating method of claim 14, wherein the first memory cell comprises a fourth switch element and a fifth switch element,
the fourth switch element is coupled in series with the first switch element, and
the fifth switch element is coupled in series with the third switch element.

16. The operating method of claim 14, further comprising:
summing the first current signal and the second current signal at a node,
wherein the first switch element is coupled to the third switch element at the node.

17. The operating method of claim 13, further comprising:
storing a second data bit by a second memory cell;
comparing the second data bit with a second search bit to generate a second current signal; and
clamping the second current signal by a third switch element according to the clamp voltage level,
wherein the third switch element is coupled in parallel with the first switch element.

18. The operating method of claim 17, further comprising:
summing the first current signal and the second current signal at a node,
wherein the first switch element is coupled to the third switch element at the node.

19. The operating method of claim 17, further comprising:
turning on a fourth switch element according to a second enable voltage level different from the first enable voltage level,
wherein the first current signal is further flows through the fourth switch element, and
the first switch element is coupled between the second switch element and the fourth switch element.

20. The operating method of claim 13, wherein before comparing the first data bit with the first search bit, the first switch element is turned on according to the first enable voltage level.
